(19) United States
(12) Patent Application Publication
(10) Pub. No.: US 2023/0268907 A1
(43) Pub. Date: Aug. 24, 2023

(54) Suspending an Electrode Structure Using a Dielectric

(71) Applicant: RF360 EUROPE GMBH, Munich (DE)

(72) Inventors: Benno Blaschke, Munich (DE); Matthias Honal, Munich (DE); Matthias Knapp, Munich (DE); Werner Ruile, Munich (DE)

(21) Appl. No.: 17/652,257

(22) Filed: Feb. 23, 2022

(51) Int. Cl. H03H 9/64; H03H 9/145; H03H 3/08

(52) U.S. Cl. CPC H03H 9/64; H03H 9/14541; H03H 3/08

(57) ABSTRACT

An apparatus is disclosed for suspending an electrode structure using a dielectric. In an example aspect, the apparatus includes a surface-acoustic-wave filter with a piezoelectric layer and an electrode structure. The electrode structure has a first surface facing the piezoelectric layer and separated from the piezoelectric layer by a distance. The surface-acoustic-wave filter also includes a dielectric disposed on at least one other surface of the electrode structure and configured to extend past a plane defined by the first surface of the electrode structure and toward the piezoelectric layer to define a cavity between at least a portion of the first surface of the electrode structure and the piezoelectric layer.

### TECHNICAL FIELD

This disclosure relates generally to wireless transceivers and other components that employ filters and, more specifically, to a surface-acoustic-wave (SAW) filter with a dielectric that suspends at least a portion of an electrode structure apart from a piezoelectric layer.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise having frequencies outside of the frequency band. It can be challenging, however, to design a filter that provides filtering for radio-frequency applications, including those that utilize frequencies above 2 gigahertz (GHz).

### SUMMARY

An apparatus is disclosed that implements techniques for suspending an electrode structure using a dielectric. In example implementations, a surface-acoustic-wave filter includes a dielectric, an electrode structure, and a piezoelectric layer. The dielectric partially encapsulates the electrode structure and suspends at least a portion of the electrode structure “above” or apart from the piezoelectric layer. Due to the suspension, a cavity is present between fingers of the electrode structure and the piezoelectric layer. In this way, the fingers are physically decoupled from the piezoelectric layer and do not create a mass load on the piezoelectric layer. This physical decoupling provides additional design flexibility and freedom in determining a thickness and material of the fingers because a target electrical conductivity can be readily optimized without the constraints of mitigating acoustic-wave dampening, acoustic loss in the electrode structure, non-linearities, and/or acoustomigration.

In an example aspect, an apparatus for filtering is disclosed. The apparatus includes a surface-acoustic-wave filter with a piezoelectric layer and an electrode structure. The electrode structure has a first surface facing the piezoelectric layer and separated from the piezoelectric layer by a distance. The surface-acoustic-wave filter also includes a dielectric disposed on at least one other surface of the electrode structure and configured to extend past a plane defined by the first surface of the electrode structure and toward the piezoelectric layer to define a cavity between at least a portion of the first surface of the electrode structure and the piezoelectric layer by the distance.

In an example aspect, an apparatus for filtering is disclosed. The apparatus includes a surface-acoustic-wave filter configured to generate a filtered signal from a radio-frequency signal. The surface-acoustic-wave filter includes means for converting the radio-frequency signal to an acoustic wave and converting a propagated acoustic wave into the filtered signal. The surface-acoustic-wave filter also includes means for propagating the acoustic wave across a planar surface to produce the propagated acoustic wave. The surface-acoustic-wave filter additional includes means for suspending at least a portion of the means for converting apart from the planar surface.

In an example aspect, a method for manufacturing a surface-acoustic-wave filter is disclosed. The method includes providing a piezoelectric layer. The method also includes providing an electrode structure having a first surface facing the piezoelectric layer and separated from the piezoelectric layer by a distance. The method additionally includes providing a dielectric that suspends at least a portion of the first surface of the electrode structure apart from the piezoelectric layer by the distance.

In an example aspect, a surface-acoustic-wave filter is disclosed. The surface-acoustic-wave filter includes a piezoelectric layer having a planar surface. The surface-acoustic-wave filter also includes an electrode structure comprising fingers. The fingers have a first surface facing the planar surface of the piezoelectric layer and a second surface facing at least partially away from the piezoelectric layer. The surface-acoustic-wave filter also includes a dielectric configured to separate the fingers of the electrode structure from the planar surface of the piezoelectric layer. The dielectric includes a cap disposed across the second surface of the fingers. The dielectric also includes spacers disposed between the piezoelectric layer and the cap through gaps that are present between the fingers.

### BRIEF DESCRIPTION OF DRAWINGS

FIG. 1 illustrates an example operating environment for suspending an electrode structure using a dielectric.

FIG. 2 illustrates an example wireless transceiver including at least one surface-acoustic-wave filter with a dielectric that suspends an electrode structure.

FIG. 3 illustrates example components of a surface-acoustic-wave filter with a dielectric that suspends an electrode structure.

FIG. 4 illustrates a first example implementation of a thin-film surface-acoustic-wave filter with a dielectric that suspends an electrode structure.

FIG. 5 illustrates a second example implementation of a thin-film surface-acoustic-wave filter with a dielectric that suspends an electrode structure.

FIG. 6 illustrates a third example implementation of a thin-film surface-acoustic-wave filter with a dielectric that suspends an electrode structure.

FIG. 7 illustrates a fourth example implementation of a thin-film surface-acoustic-wave filter with a dielectric that suspends an electrode structure.

FIG. 8 illustrates a fifth example implementation of a thin-film surface-acoustic-wave filter with a dielectric that suspends an electrode structure.

FIG. 9 is a flow diagram illustrating an example process for manufacturing a surface-acoustic-wave filter with a dielectric that suspends an electrode structure.

### DETAILED DESCRIPTION

To transmit or receive radio-frequency signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material as a vibrating medium, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electrical and acoustic waves.

The acoustic wave propagates across the piezoelectric material at a velocity having a magnitude that is significantly less than that of the propagation velocity of the electrical wave. Generally, the magnitude of the propagation velocity of a wave is proportional to a size of a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones.

Some acoustic filters have an electrode structure that is either directly in physical contact with a piezoelectric material or separated by a thin dielectric layer, such as a dielectric layer with a thickness less than 20 nanometers. This direct or indirect physical contact can generate undesired side effects, such as acoustic losses in the electrode structure, non-linearities, and/or acoustomigration. In some cases, the acoustomigration can deteriorate the acoustic properties of the filter and/or cause fingers of the electrode structure to be short circuited over time.

Also, due to the direct or indirect physical contact, the fingers of the electrode structure create a mass load on the piezoelectric material. This mass load can dampen the acoustic wave, which can impair filter performance and further complicate the design of the acoustic filter. Consider the trade-off made between electrical conductivity and acoustic-wave dampening. Increasing a thickness of the fingers, for instance, can increase electrical conductivity. However, increasing finger thickness also increases the mass load, which can further dampen the acoustic wave and degrade the performance of the acoustic filter. As a result, an acoustic filter's electrical conductivity is at least partially constrained to ensure adequate generation and propagation of the acoustic wave.

Some techniques can mitigate the undesired side effects (e.g., acoustic loss, non-linearities, or acoustomigration) by optimizing the metal layers of the electrode structure. However, the trade-off between electrical conductivity and acoustic-wave dampening can still constrain a design of the acoustic filter.

To address this challenge, techniques for suspending an electrode structure using a dielectric are described. In example implementations, a surface-acoustic-wave filter includes a dielectric, an electrode structure, and a piezoelectric layer. The dielectric partially encapsulates the electrode structure and suspends at least a portion of the electrode structure “above” or apart from the piezoelectric layer. Due to the suspension, a cavity is present between fingers of the electrode structure and the piezoelectric layer. In this way, the fingers are physically decoupled from the piezoelectric layer and do not create a mass load on the piezoelectric layer. This physical decoupling provides additional design flexibility and freedom in determining a thickness and material of the fingers because a target electrical conductivity can be readily optimized without the constraints of mitigating acoustic-wave dampening, acoustic loss in the electrode structure, non-linearities, and/or acoustomigration. These techniques can be used with, and provide benefits for, acoustic filters that support frequencies above 2 GHz as well as for other acoustic filters that support frequencies below 2 GHz.

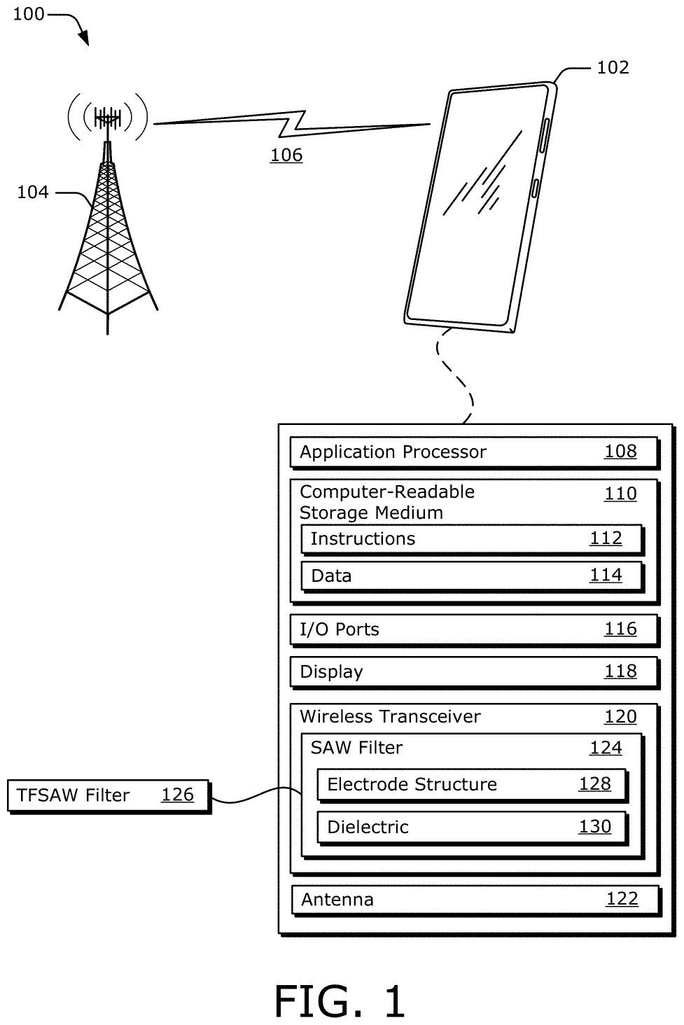

FIG. 1 illustrates an example environment 100 for suspending an electrode structure using a dielectric. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one surface-acoustic-wave filter 124. In some implementations, the wireless transceiver 120 includes multiple surface-acoustic-wave filters 124, which can be formed from surface-acoustic-wave resonators arranged in series, in parallel, in a ladder structure, in a lattice structure, or some combination thereof. The surface-acoustic-wave filter 124 can be a thin-film surface-acoustic-wave filter 126 (TFSAW filter 126) or another type of surface-acoustic-wave filter not shown, such as a high-quality temperature-compensated surface-acoustic-wave filter (HQ-TC SAW filter). In general, the surface-acoustic-wave filter 124 can be any type of surface-acoustic-wave filter with sufficient electromechanical coupling coefficient (k²) (e.g., with an electromechanical coupling coefficient that is greater than a design threshold).

The surface-acoustic-wave filter 124 includes at least one electrode structure 128 and a dielectric 130 (e.g., dielectric material or at least one dielectric layer). The dielectric 130 partially encapsulates the electrode structure 128 and suspends at least a portion of the electrode structure 128 above a piezoelectric layer of the surface-acoustic-wave filter 124. In particular, the dielectric 130 enables a cavity to form between fingers of the electrode structure 128 and the piezoelectric layer. This cavity enables the fingers of the electrode structure 128 to be physically decoupled from the piezoelectric layer. In other words, the dielectric 130 maintains a separation between the fingers of the electrode structure 128 and the piezoelectric layer.

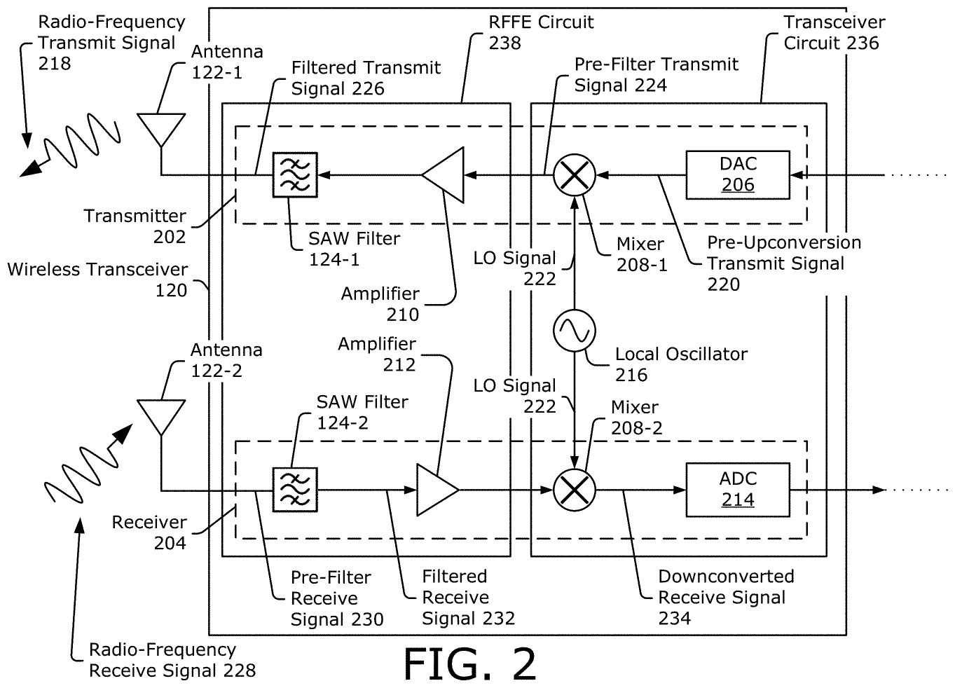

Suspending the fingers of the electrode structure 128 can cause the electromechanical coupling coefficient of the surface-acoustic-wave filter 124 to decrease. However, the distance between the electrode structure 128 and the piezoelectric layer (e.g., a height of the cavity) can be determined to enable a target electromechanical coupling coefficient to be realized. By suspending the fingers, some negative side effects associated with direct or indirect physical contact can be avoided. These negative side effects can include acoustic losses in the electrode structure 128, non-linearities, and/or acoustomigration. Furthermore, the electrical conductivity of the electrode structure is no longer constrained by acoustic-wave dampening. The surface-acoustic-wave filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first surface-acoustic-wave filter 124-1. The receiver 204 includes at least one second surface-acoustic-wave filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the surface-acoustic-wave filter 124-1 of the transmitter 202, the surface-acoustic-wave filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an unconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first surface-acoustic-wave filter 124-1.

The first surface-acoustic-wave filter 124-1 filters the amplified pre-filter transmit signal 224 to generate a filtered transmit signal 226. As part of the filtering process, the first surface-acoustic-wave filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second surface-acoustic-wave filter 124-2 accepts the received radio-frequency receive signal 228, which is represented by a pre-filter receive signal 230. The second surface-acoustic-wave filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

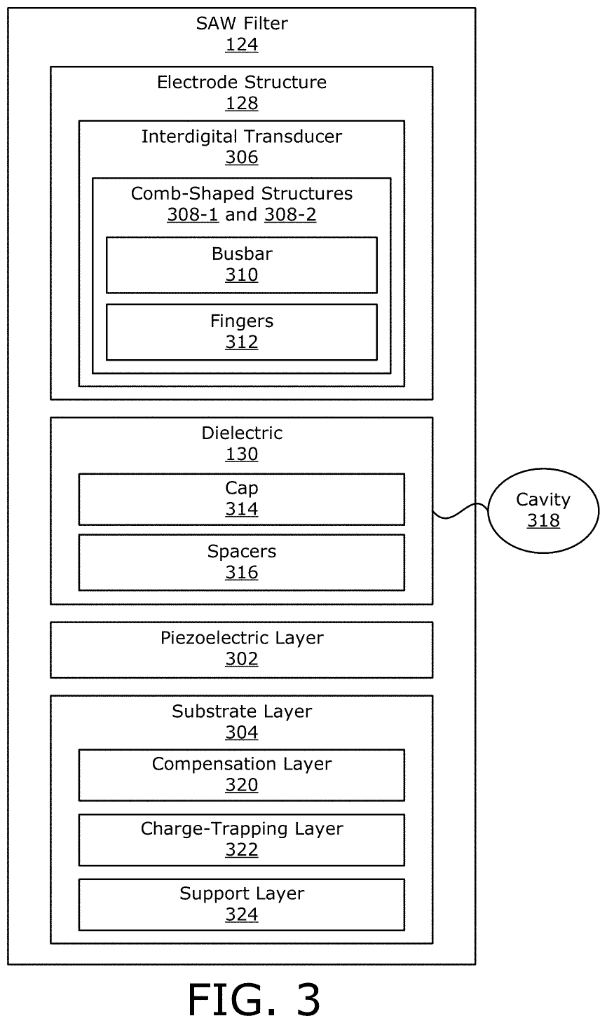

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which surface-acoustic-wave filters 124 may be included. For example, the surface-acoustic-wave filters 124 can be integrated within duplexers or diplexers of the wireless transceiver 120. Example implementations of the surface-acoustic-wave filter 124-1 or 124-2 are further described with respect to FIGS. 3 to 8.

FIG. 3 illustrates example components of the surface-acoustic-wave filter 124. In the depicted configuration, the surface-acoustic-wave filter 124 includes the electrode structure 128, the dielectric 130 (e.g., dielectric material), at least one piezoelectric layer 302, and at least one substrate layer 304. The electrode structure 128 comprises an electrically conductive material, such as metal, and can include one or more layers. The one or more layers can include one or more metal layers and can optionally include one or more adhesion layers. As an example, the metal layers can be composed of aluminium (Al), copper (Cu), silver (Ag), gold (Au), tungsten (W), or some combination or doped version thereof. The adhesion layers can be composed of chromium (Cr), titanium (Ti), molybdenum (Mo), or some combination thereof.

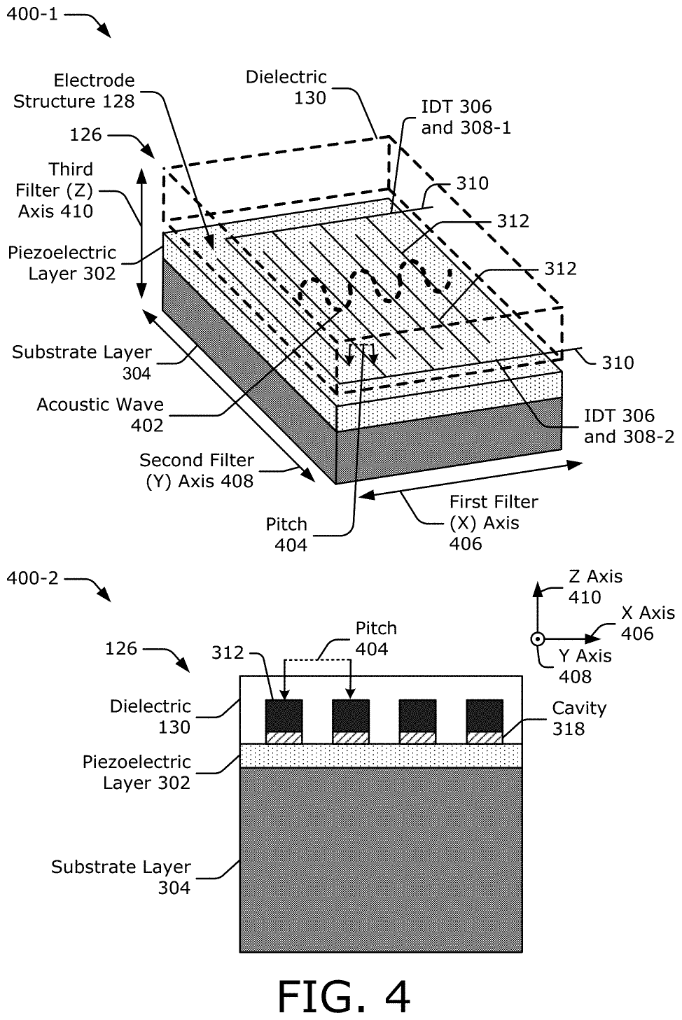

The electrode structure 128 can include one or more interdigital transducers 306. The interdigital transducer 306 converts an electrical signal into an acoustic wave and converts the acoustic wave into a filtered electrical signal. The interdigital transducer 306 includes at least two comb-shaped structures 308-1 and 308-2. Each comb-shaped structure 308-1 and 308-2 includes a busbar 310 (e.g., a conductive segment or rail) and multiple fingers 312 (e.g., electrode fingers). In some examples, thicknesses of the fingers 312 can be between approximately 100 and 1,500 nanometers. An example interdigital transducer 306 is further described with respect to FIG. 4. Although not explicitly shown, the electrode structure 128 can also include two or more reflectors. In an example implementation, the interdigital transducer 306 is arranged between two reflectors, which reflect the acoustic wave back towards the interdigital transducer 306.

The dielectric 130 includes at least one cap 314 and multiple spacers 316. The cap 314 refers to a portion of the dielectric 130 that can be disposed on the electrode structure 128. In this case, the cap 314 is at least disposed across a portion of a length of the fingers 312. In example implementations, the cap 314 is disposed across a majority of the length of the fingers 312. Optionally, the cap 314 can also be disposed across the busbar 310, the reflectors, or other parts of the chip. A thickness of the cap 314 can be approximately 100 nanometers or more (e.g., approximately 200, 500, 1,000, or 2,000 nanometers).

In general, the cap 314 adheres to the electrode structure 128 and functions as a foundation or framework for suspending the electrode structure 128. In some aspects, the cap 314 can also serve as a main layer of a hermetic package. Additional dielectric layers can be disposed on the cap 314 to provide protection against humidity.

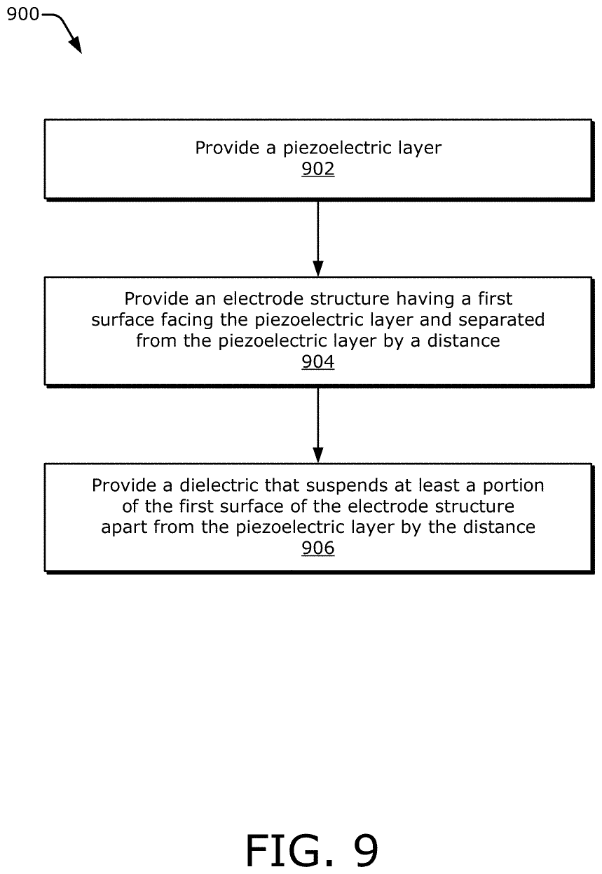

The spacers 316 are disposed between portions of the piezoelectric layer 302 and the cap 314 through gaps within the electrode structure 128 (e.g., gaps between the fingers 312). In some cases, the spacers 316 are also disposed between the busbar 310 and the piezoelectric layer 302. Additionally or alternatively, the spacers 316 can be disposed between the reflectors and the piezoelectric layer 302. In this way, the spacers 316 support the busbar 310 and/or the reflectors and provide access holes and feeder lines for etching, which is explained in further detail with respect to FIG. 9. In general, the spacers 316 can have thicknesses that are greater than the thicknesses of the fingers 312. The spacers 316 provide structural support to elevate the cap 314 above the piezoelectric layer 302. By elevating the cap 314, the spacers 316 suspend at least a portion of the electrode structure 128 (e.g., at least a portion of the fingers 312) apart from the piezoelectric layer 302. In other words, the spacers 316 have a size sufficient to physically separate the portion of the electrode structure 128 from the piezoelectric layer 302.

A cavity 318 (or gap) forms between the suspended electrode structure 128 and the piezoelectric layer 302. The cavity 318 can include a gas, such as air. In some implementations, a height of the cavity 318 is between approximately 1 and 50 nanometers. For example, the height of the cavity 318 can be approximately 10, 30, or 50 nanometers. In general, the term “approximately” can mean that any of the heights can be within +/−10% of a specified value or less (e.g., within +/−5%, +/−3%, or +/−2% of a specified value).

The height of the cavity 318 is determined to enable a target electromechanical coupling coefficient to be achieved while realizing the benefits associated with suspending the electrode structure 128. For example, the height of the cavity 318 can be approximately 10 nanometers to realize an electromechanical coupling coefficient of approximately 7%. Increasing the height of the cavity 318 can decrease the electromechanical coupling coefficient. Also, decreasing the height of the cavity 318 can increase the electromechanical coupling coefficient.

The spacers 316 provide stability and support to prevent the cavity 318 from collapsing. The spacers 316 also reflect the surface acoustic wave. In some implementations, the spacers 316 are positioned at nodes of a standing surface acoustic wave to minimize dampening.

The dielectric 130 can be formed using a variety of different types of dielectric material, such as silicon dioxide (SiO₂), carbon doped oxide film (SiCOH), nitride, aluminum oxide (Al₂O₃), a polymer (e.g., bensocyclobutene (BCB) or polyimide), titanium dioxide (TiO₂), hafnium dioxide (HfO₂), yttrium oxide (Y₂O₃), zirconium dioxide (ZrO₂), or some combination or doped version thereof. In some implementations, the dielectric is composed of multiple layers. The multiple layers can be formed using the same material or different materials. Also, the cap 314 and the spacers 316 can be implemented using the same material or different materials.

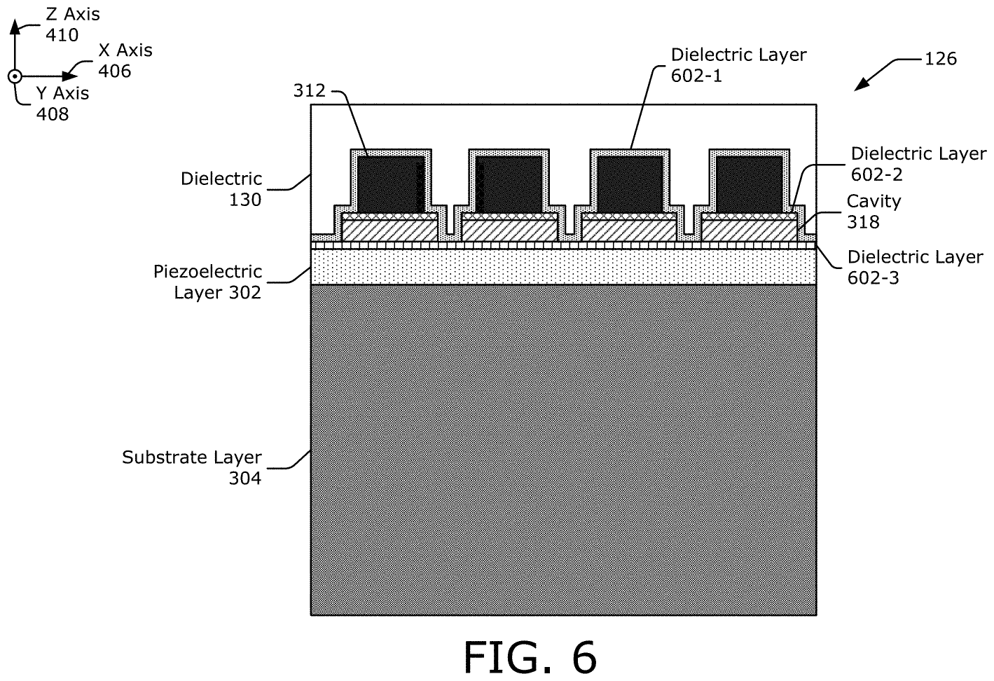

In some implementations, the surface-acoustic-wave filter 124 includes additional dielectric layers, such as one or more of the dielectric layers shown in FIG. 6. This dielectric layer can serve as an etch stop or a barrier layer during the manufacturing process. Additionally or alternatively, the dielectric layer serves as a seal or layer of protection from an external elements.

In example implementations, the piezoelectric layer 302 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), quartz, aluminium nitride (AlN), aluminium scandium nitride (AlScN), or some combination thereof. In general, the material that forms the piezoelectric layer 302 has a crystalline structure. This crystalline structure is defined by an ordered arrangement of particles (e.g., atoms, ions, or molecules). In some aspects, the material and crystalline structure of the piezoelectric layer 302 are selected such that the piezoelectric layer has a shear mode, a Rayleigh mode, or a longitudinal mode.

The substrate layer 304 includes one or more sublayers that can support passivation, temperature compensation, power handling, mode suppression, and so forth. As an example, the substrate layer 304 can include at least one compensation layer 320, at least one charge-trapping layer 322, at least one support layer 324, or some combination thereof. These sublayers can be considered part of the substrate layer 304 or their own separate layers.

The compensation layer 320 can provide temperature compensation to enable the surface-acoustic-wave filter 124 to achieve a target temperature coefficient of frequency based on the thickness of the piezoelectric layer 302. In some implementations, a thickness of the compensation layer 320 can be tailored to provide mode suppression (e.g., suppress the spurious plate mode). In example implementations, the compensation layer 320 can be implemented using at least one silicon dioxide (SiO₂) layer, at least one doped silicon dioxide layer, at least one silicon nitride layer, at least one silicon oxynitride layer, or some combination thereof. In some applications, the substrate layer 304 may not include, for instance, the compensation layer 320 to reduce cost of the surface-acoustic-wave filter 124.

The charge-trapping layer 322 can trap induced charges at the interface between the compensation and support layer in order to, for example, suppress nonlinear substrate effects. The charge-trapping layer 322 can include at least one polysilicon (poly-Si) layer (e.g., a polycrystalline silicon layer or a multicrystalline silicon layer), at least one amorphous silicon layer, at least one silicon nitride (SiN) layer, at least one silicon oxynitride (SiON) layer, at least one aluminium nitride (AlN) layer, diamond-like carbon (DLC), diamond, or some combination thereof.

The support layer 324 can enable the acoustic wave to form across the surface of the piezoelectric layer 302 and reduce the amount of energy that leaks into the substrate layer 304. In some implementations, the support layer 324 can also act as a compensation layer 320. In general, the support layer 324 is composed of material that is non-conducting and provides isolation. For example, the support layer 324 can be formed using silicon (Si) material (e.g., a doped high-resistive silicon material), sapphire material (e.g., aluminium oxide (Al₂O₃)), silicon carbide (SiC) material, fused silica material, quartz, glass, diamond, or some combination thereof. In some implementations, the support layer 324 has a relatively similar thermal expansion coefficient (TEC) as the piezoelectric layer 302. The support layer 324 can also have a particular crystal orientation to support the suppression or attenuation of spurious modes.

In some aspects, the surface-acoustic-wave filter 124 can be considered a resonator. Sometimes the surface-acoustic-wave filter 124 can be connected to other resonators associated with different layer stacks than the surface-acoustic-wave filter 124. In other aspects, the surface-acoustic-wave filter 124 can be implemented as multiple interconnected resonators, which use the same layers (e.g., the piezoelectric layer 302 and/or the substrate layer 304). The electrode structure 128 and the dielectric 130 are further described with respect to FIG. 4.

FIG. 4 illustrates an example implementation of the thin-film surface-acoustic-wave filter 126 with the dielectric 130 suspending the electrode structure 128. A three-dimensional perspective view 400-1 of the thin-film surface-acoustic-wave filter 126 is shown at the top of FIG. 4, and a two-dimensional cross-section view 400-2 of the thin-film surface-acoustic-wave filter 126 is shown at the bottom of FIG. 4.

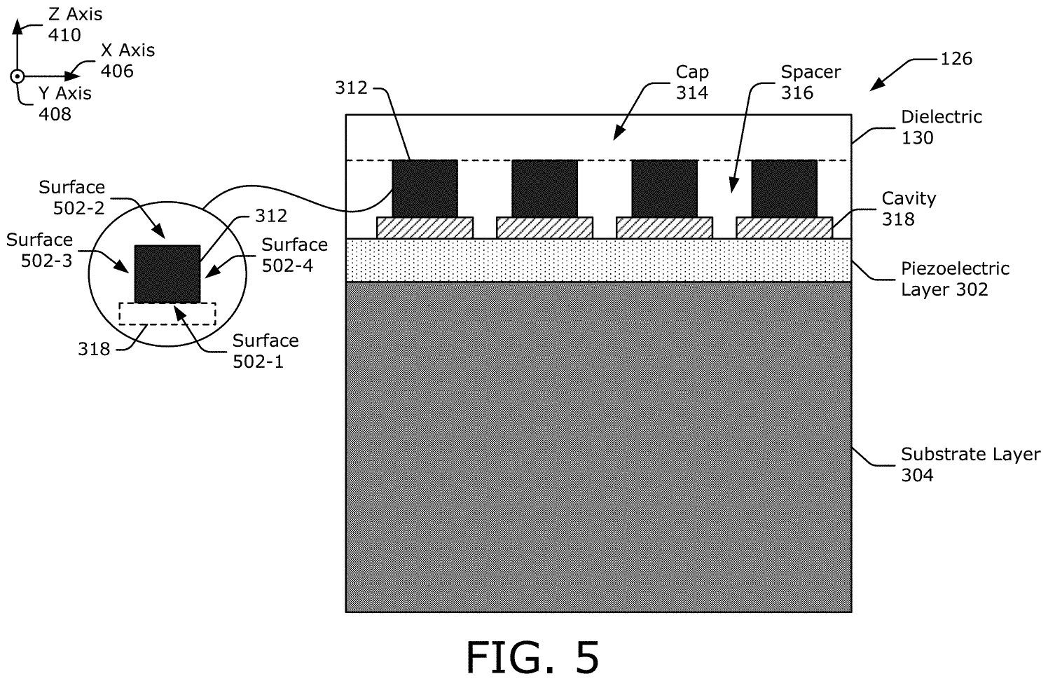

The thin-film surface-acoustic-wave filter 126 includes the electrode structure 128, the dielectric 130, the piezoelectric layer 302, and at least one substrate layer 304. The electrode structure 128 can include one or more interdigital transducers 306. In the depicted configuration shown in the two-dimensional cross-section view 400-2, the piezoelectric layer 302 is disposed between the dielectric 130 and the substrate layer 304. The dielectric 130 encapsulates (e.g., surrounds, is in physical contact with, or is at least proximate to) at least one other surface of the fingers 312, which is facing at least partially away from the piezoelectric layer 302. The cap 314 and spacers 316 of the dielectric 130 are further described with respect to FIG. 5. In some implementations, the dielectric 130 is disposed across the busbars 310 of the electrode structure 128, as shown in FIG. 4.

The dielectric 130 forms a cavity 318 between the fingers 312 and the piezoelectric layer 302. In some cases, the cavity 318 can be considered a collection of multiple cavities that do not intersect. In other cases, the cavity 318 can be considered a single cavity with intersecting branches. Sometimes a width of the cavity 318 can be approximately equal to the width of the fingers 312. In general, the term “approximately” can mean that any of the widths can be within +/−10% of a specified value or less (e.g., within +/−5%, +/−3%, or +/−2% of a specified value). In other implementations, the width of the cavity 318 can be greater than the width of the fingers 312, as further described with respect to FIG. 5. In some aspects, the dielectric 130 does not form a cavity between the busbars 310 and the piezoelectric layer 302. Some package structures can have an outer layer that is formed by the dielectric 130. Other package structures can have an outer layer that is different than the dielectric 130. In some cases, the dielectric 130 and the outer layer are separated by a distance, and another cavity is present between the dielectric 130 and the outer layer of the package.

In the three-dimensional perspective view 400-1, the interdigital transducer 306 is shown to have the two comb-shaped structures 308-1 and 308-2 with fingers 312 extending from two busbars 310 towards each other. The fingers 312 are arranged in an interlocking manner in between the two busbars 310 of the interdigital transducer 306 (e.g., arranged in an interdigitated manner). In other words, the fingers 312 connected to a first busbar 310 extend towards a second busbar 310 but do not connect to the second busbar 310. Likewise, fingers 312 connected to the second busbar 310 extend towards the first busbar 310 but do not connect to the first busbar 310.

In the direction along the busbars 310, there is an overlap region including a central region where a portion of one finger 312 overlaps with a portion of an adjacent finger 312. This central region, including the overlap, may be referred to as the aperture, track, or active region where electric fields are produced between fingers 312 to cause an acoustic wave 402 to form at least in this region of the piezoelectric layer 302.

A physical periodicity of the fingers 312 is referred to as a pitch 404 of the interdigital transducer 306. The pitch 404 may be indicated in various ways. For example, in certain aspects, the pitch 404 may correspond to a magnitude of a distance between adjacent fingers 312 of the interdigital transducer 306 in the central region. This distance may be defined, for example, as the distance between center points of each of the fingers 312. The distance may be generally measured between a right (or left) edge of one finger 312 and the right (or left) edge of an adjacent finger 312 when the fingers 312 have uniform widths. In certain aspects, an average of distances between adjacent fingers 312 of the interdigital transducer 306 may be used for the pitch 404. The frequency at which the piezoelectric layer 302 vibrates is a main-resonance frequency of the electrode structure 128. The frequency is determined at least in part by the pitch 404 of the interdigital transducer 306 and other properties of the thin-film surface-acoustic-wave filter 126.

In the three-dimensional perspective view 400-1, the thin-film surface-acoustic-wave filter 126 is defined by a first (X) axis 406, a second (Y) axis 408, and a third (Z) axis 410. The first axis 406 and the second axis 408 are parallel to a planar surface of the piezoelectric layer 302, and the second axis 408 is perpendicular to the first axis 406. The third axis 410 is normal (e.g., perpendicular) to the planar surface of the piezoelectric layer 302. The busbars 310 of the interdigital transducer 306 are oriented to be parallel to the first axis 406. The fingers 312 of the interdigital transducer 306 are orientated to be parallel to the second axis 408. Also, an orientation of the piezoelectric layer 302 causes an acoustic wave 402 to mainly form in a direction of the first axis 406. As such, the acoustic wave 402 forms in a direction that is substantially perpendicular to the direction of the fingers 312 of the interdigital transducer 306.

During operation, the surface-acoustic-wave filter 124 (e.g., the thin-film surface-acoustic-wave filter 126 of FIG. 4 or another type of surface-acoustic-wave filter) accepts a radio-frequency signal, such as the pre-filter transmit signal 224 or the pre-filter receive signal 230 shown in FIG. 2. The electrode structure 128 excites an acoustic wave 402 on the piezoelectric layer 302 using the inverse piezoelectric effect. For example, the interdigital transducer 306 in the electrode structure 128 generates an alternating electric field based on the accepted radio-frequency signal. The piezoelectric layer 302 enables the acoustic wave 402 to be formed in response to the alternating electric field generated by the interdigital transducer 306. In other words, the piezoelectric layer 302 causes, at least partially, the acoustic wave 402 to form responsive to electrical stimulation by one or more interdigital transducers 306.

The acoustic wave 402 propagates across the piezoelectric layer 302 and interacts with the interdigital transducer 306 or another interdigital transducer within the electrode structure 128 (not shown in FIG. 4). The acoustic wave 402 that propagates can be a standing wave. In some implementations, two reflectors within the electrode structure 128 cause the acoustic wave 402 to be formed as a standing wave across a portion of the piezoelectric layer 302. In other implementations, the acoustic wave 402 propagates across the piezoelectric layer 302 from the interdigital transducer 306 to another interdigital transducer (not shown).

Using the piezoelectric effect, the electrode structure 128 generates a filtered radio-frequency signal based on the propagated surface acoustic wave 402. In particular, the piezoelectric layer 302 generates an alternating electric field due to the mechanical stress generated by the propagation of the acoustic wave 402. The alternating electric field induces an alternating current in the other interdigital transducer or the interdigital transducer 306. This alternating current forms the filtered radio-frequency signal, which is provided at an output of the surface-acoustic-wave filter 124. The filtered radio-frequency signal can include the filtered transmit signal 226 or the filtered receive signal 232 of FIG. 2.

It should be appreciated that while a certain number of fingers are illustrated in FIG. 4, the number of actual fingers and lengths and width of the fingers and busbars may be different in an actual implementation. Such parameters depend on the particular application and desired filter characteristics. In addition, the thin-film surface-acoustic-wave filter 126 or another type of surface-acoustic-wave filter can include multiple interconnected electrode structures each including multiple interdigital transducers 306 to achieve a desired passband (e.g., multiple interconnected resonators or interdigital transducers 306 in series or parallel connections to form a desired filter transfer function).

Although not explicitly shown, the electrode structure 128 can also include two or more reflectors. In an example implementation, the interdigital transducer 306 is arranged between two reflectors (not shown), which reflect the acoustic wave 402 back towards the interdigital transducer 306. Each reflector within the electrode structure 128 can have two busbars and a grating structure of conductive fingers that each connect to both busbars. In some implementations, the pitch of the reflector can be similar to or the same as the pitch 404 of the interdigital transducer 306 to reflect the acoustic wave 402 in the resonant frequency range. Features of the dielectric 130 are further described with respect to FIG. 5.

FIG. 5 illustrates another example implementation of a thin-film surface-acoustic-wave filter 126 with the dielectric 130 suspending the electrode structure 128. In the depicted configuration, the fingers 312 of the electrode structure 128 are shown to have four surfaces 502-1, 502-2, 502-3, and 502-4. The surfaces 502-1 and 502-2 can be substantially parallel to each other. Also, the surfaces 502-3 and 502-4 can be substantially parallel to each other and normal to the surfaces 502-1 and 502-2. The surface 502-1 faces the piezoelectric layer 302 and is proximate to the piezoelectric layer 302. The surface 502-1 is separated from the piezoelectric layer 302 by a distance. This distance can correspond to a height of the cavity 318. The surface 502-2 is opposite the surface 502-1 and faces at least partially away from the piezoelectric layer 302. In some aspects, the third (Z) filter axis 410 is substantially normal to the surfaces 502-1 and 502-2. The surfaces 502-3 and 502-4 are adjacent to the surfaces 502-1 and 502-2. The first (X) axis 406 can be substantially normal to the surfaces 502-3 and 502-4.

As shown in FIG. 5, the dielectric 130 encapsulates or surrounds at least a portion of the surfaces 502-2 to 502-4 of the fingers 312. The dielectric 130 extends past a plane defined by the first surface 502-1 of the electrode structure 128 and towards the piezoelectric layer 302 to define the cavity 318. A dashed line is illustrated in FIG. 5 to distinguish between the cap 314 and the spacers 316 of the dielectric 130. In this case, the cap 314 represents a portion of the dielectric 130 that is disposed on the surface 502-2 of the fingers 312 and/or disposed on the spacers 316. The spacers 316 represent a portion of the dielectric 130 that is disposed between the surfaces 502-3 and 502-4 of adjacent fingers 312. In general, the spacers 316 include the portion of the dielectric 130 that extends past the first surface 502-1 towards the piezoelectric layer 302. In some implementations, the spacers 316 abut the piezoelectric layer 302.

Although not explicitly shown, the electrode structure 128 can also have two other surfaces, which are substantially normal to the second (Y) axis 408. The dielectric 130 can optionally encapsulate or surround at least a portion of these surfaces.

Along the second (Y) axis 408, the spacer 316 can be implemented as one contiguous piece. Alternatively, the spacer 316 can be implemented using multiple pieces that are physically separated from each other along the second (Y) axis 408. In some implementations, a length of the spacer 316 along the second (Y) axis 408 can be approximately equal to a length of an adjacent cavity 318. In other implementations, the length of the spacer 316 along the second (Y) axis 408 is less than the length of the adjacent cavity 318 but greater than half the length of the adjacent cavity 318. In still other implementations, the length of the spacer 316 is greater than the length of the adjacent cavity 318.

Along the first (X) axis 406 and/or the second (Y) axis 408, the cap 314 can be implemented as one contiguous piece. Alternatively, the cap 314 can be implemented using multiple pieces that are physically separated from each other along the first (X) axis 406 and/or the second (Y) axis 408. In general, the cap 314 is disposed on the spacers 316. In some cases, the cap 314 is also disposed on at least a portion of the electrode structure 128, such as across at least a portion of the fingers 312, at least a portion of the busbar 310, and/or at least a portion of the reflectors.

The thin-film surface-acoustic-wave filter 126 of FIG. 5 is similar to the thin-film surface-acoustic-wave filter 126 of FIG. 4, except the width of the cavity 318 is greater than the width of the fingers 312. In other words, the width of the cavity 318 extends past the width of the fingers 312. As an example, the width of the cavity 318 can be approximately 1%, 5%, or 10% greater than the width of the finger 312. In general, the width of the cavity 318 is constrained by a target width of the spacers 316 for providing structural support for suspending the electrode structure 128. The thin-film surface-acoustic-wave filter 126 can also include additional dielectric layers, as further described with respect to FIG. 6.

FIG. 6 illustrates yet another example implementation of a thin-film surface-acoustic-wave filter 126 with the dielectric 130 suspending the electrode structure 128. In the depicted configuration, the thin-film surface-acoustic-wave filter 126 includes dielectric layers 602-1, 602-2, and 602-3. In other implementations, the thin-film surface-acoustic-wave filter 126 includes a subset of the dielectric layers 602-1, 602-2, and/or 602-3 or additional dielectric layers not shown. In some cases, the dielectric layers 602-1 to 602-3 serve as etch stop or barrier layers during the manufacturing of the thin-film surface-acoustic-wave filter 126.

The dielectric layer 602-1 is disposed between the dielectric 130 and the piezoelectric layer 302, between the dielectric 130 and the cavity 318, and between the dielectric 130 and the surfaces 502-2 to 502-4 of the fingers 312. In an example implementation, the dielectric layer 602-1 can have a thickness between approximately 1 and 100 nanometers. The dielectric layer 602-2 is disposed on the surface 502-1 of the fingers 312. As such, the dielectric layer 602-2 is between the fingers 312 and the cavity 318. The dielectric layer 602-3 is disposed on a surface of the piezoelectric layer 302. As such, the dielectric layer 602-3 is between the piezoelectric layer 302 and the dielectric 130, and between the piezoelectric layer 302 and the cavity 318. Thicknesses of the dielectric layers 602-2 and 602-3 can be between approximately 1 and 5 nanometers.

Although described with respect to a thin-film surface-acoustic-wave filter 126, the techniques for suspending the electrode structure 128 using the dielectric 130 can also be applied to other types of surface-acoustic-wave filters. For example, a compensation layer 320 of a high-quality temperature-compensated surface-acoustic-wave filter can act as the dielectric 130 and suspend the electrode structure 128 of the high-quality temperature-compensated surface-acoustic-wave filter. In this way, the compensation layer 320 can provide temperature compensation to enable the high-quality temperature-compensated surface-acoustic-wave filter to achieve a target temperature coefficient of frequency while also suspending the electrode structure 128. As an example, the compensation layer 320 can be implemented using at least one silicon dioxide layer.

One of ordinary skill in the art can appreciate the variety of other configurations for which the dielectric 130 can suspend the electrode structure 128. For example, some implementations may have one or more gaps between the fingers 312 that do not include a spacer 316. In this case, the cap 314 may extend down a portion of the surface 502-3 or 502-4 of the finger 312 along which the spacer 316 is not present. Also, the spacer 316 may be a contiguous piece or multiple pieces that extend along the second (Y) axis 408. The length of the spacer 316 along the second (Y) axis 408 can be determined to provide sufficient structural support for suspending the electrode structure 128. Also the height and width of the cavity 318 can be determined to realize a target electromechanical coupling coefficient and avoid the negative side effects of a physical coupling between the electrode structure 128 and the piezoelectric layer 302.

As another example, other implementations may not include the cap 314 or the cap 314 may be disposed across a portion of the fingers 312. Consider a case in which the cap 314 is disposed across the spacers 316 and extend across a portion of the widths of the fingers 312 along the first (X) axis 406. In this manner, the caps 314 that are associated with adjacent spacers 316 are physically separate. In another case, the cap 314 extends across a portion of the lengths of the fingers 312 along the second (Y) axis 408. Also, the cap 314 may include a contiguous piece or multiple pieces that extend along the first (X) axis 406 and/or the second (Y) axis 408.

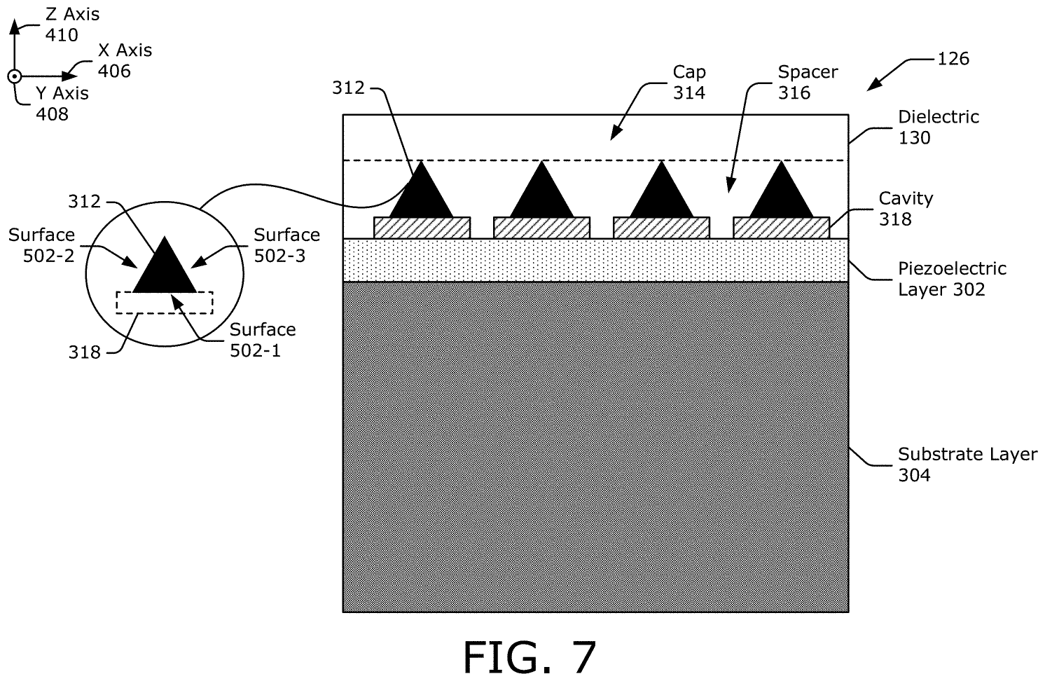

FIG. 7 illustrates another example implementation of a thin-film surface-acoustic-wave filter 126 with the dielectric 130 suspending the electrode structure 128. The thin-film surface-acoustic-wave filter 126 of FIG. 7 is similar to the thin-film surface-acoustic-wave filter 126 of FIG. 5, except the fingers 312 of FIG. 7 have a triangular shape instead of a rectangular shape. In the depicted configuration, the fingers 312 of the electrode structure 128 are shown to have three surfaces 502-1, 502-2, and 502-3. The surface 502-1 faces the piezoelectric layer 302 and is proximate to the piezoelectric layer 302. The surfaces 502-2 and 502-3 face at least partially away from the piezoelectric layer 302.

As shown in FIG. 7, the dielectric 130 encapsulates or surrounds the surfaces 502-2 and 502-3 of the fingers 312. A dashed line is illustrated in FIG. 7 to distinguish between the cap 314 and the spacers 316 of the dielectric 130. In this case, the cap 314 represents a portion of the dielectric 130 that is disposed on the spacers 316. The spacers 316 represent a portion of the dielectric 130 that is disposed between the surfaces 502-2 and 502-3 of adjacent fingers 312.

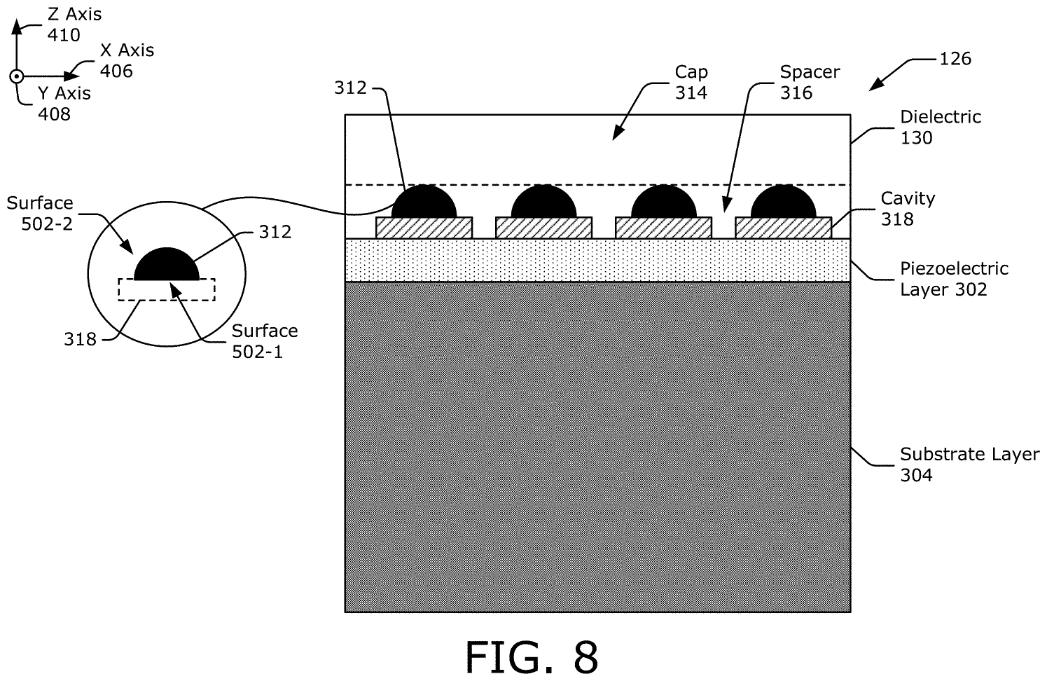

FIG. 8 illustrates yet another example implementation of a thin-film surface-acoustic-wave filter 126 with the dielectric 130 suspending the electrode structure 128. The thin-film surface-acoustic-wave filter 126 of FIG. 8 is similar to the thin-film surface-acoustic-wave filters 126 of FIGS. 5 and 7, except the fingers 312 of FIG. 8 have a rounded shape instead of a rectangular or triangular shape. In the depicted configuration, the fingers 312 of the electrode structure 128 are shown to have two surfaces 502-1 and 502-2. The surface 502-1 faces the piezoelectric layer 302 and is proximate to the piezoelectric layer 302. The surface 502-2 faces at least partially away from the piezoelectric layer 302.

As shown in FIG. 8, the dielectric 130 encapsulates or surrounds the surface 502-2 of the fingers 312. A dashed line is illustrated in FIG. 8 to distinguish between the cap 314 and the spacers 316 of the dielectric 130. In this case, the cap 314 represents a portion of the dielectric 130 that is disposed on the surface 502-2 of the fingers 312 and disposed on the spacers 316. The spacers 316 represent a portion of the dielectric 130 that is disposed between the surface 502-2 of adjacent fingers 312.

Although not explicitly shown in FIGS. 5, 7, and 8, other implementations of thin-film surface-acoustic-wave filters 126 can have the dielectric 130 disposed at least partially on one or more of the surfaces 502-2 to 502-4. In some cases, the spacers 316 of the dielectric 130 are sufficient for suspending the electrode structure 128. Accordingly, the dielectric 130 can optionally be implemented without the cap 314. In other words, some implementations of the dielectric 130 may include spacers 316 and may not include the cap 314.

Although the techniques for suspending an electrode structure 128 using a dielectric 130 are described with respect to thin-film surface-acoustic-wave filters 126 in FIGS. 4 to 8, these techniques can also be applied to other types of surface-acoustic-wave filters 124. For example, these techniques can be applied to a surface-acoustic-wave filter 124 that includes the electrode structure 128, the dielectric 130, and the piezoelectric layer 302, and does not include the substrate layer 304. Explained another way, these techniques can be applied to a surface-acoustic-wave filter 124 with a substrate layer 304 that is formed using the same piezoelectric material as the piezoelectric layer 302.

FIG. 9 is a flow diagram illustrating an example process 900 for manufacturing a surface-acoustic-wave filter 124 with a dielectric that suspends an electrode structure. The process 900 is described in the form of a set of blocks 902-906 that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the process 900, or an alternative process. Operations represented by the illustrated blocks of the process 900 may be performed to manufacture the surface-acoustic-wave filter 124 (e.g., of FIGS. 1 to 3). More specifically, the operations of the process 900 may be performed, at least in part, to suspend at least a portion of an electrode structure 128 using a dielectric 130 (e.g., of FIGS. 4 to 8).

At 902, a piezoelectric layer is provided. For example, a manufacturing process provides a piezoelectric layer 302, as shown in FIGS. 4 to 8. The piezoelectric layer 302 can be implemented using materials such as lithium niobate, lithium tantalate, quartz, aluminium nitride, aluminium scandium nitride, or some combination thereof. In some aspects, a structure of the piezoelectric layer 302 is tailored to enable the piezoelectric layer 302 to have or support a shear mode, a Rayleigh mode, or a longitudinal mode.

At 904, an electrode structure is provided having a first surface facing the piezoelectric layer and separated from the piezoelectric layer by a distance. For example, the manufacturing process provides the electrode structure 128, as shown in FIGS. 4 to 8. The electrode structure 128 includes the first surface 502-1, which faces the piezoelectric layer 302 as shown in FIGS. 5, 7, and 8. The first surface 502-1 is separated from the piezoelectric layer 302 by a distance. Example distances can be between approximately 1 and 50 nanometers. The electrode structure 128 can also have at least one other surface, such as any of the surfaces 502-2, 502-3, and/or 502-4 shown in FIG. 5, 7, or 8. The electrode structure 128 can be formed using an electrically conductive material, such as metal.

At 906, a dielectric that suspends at least a portion of the first surface of the electrode structure apart from the piezoelectric layer by the distance is provided. For example, the manufacturing process provides the dielectric 130, which suspends at least a portion of the first surface 502-1 of the electrode structure 128 apart from the piezoelectric layer 302 by the distance, as shown in FIGS. 4 to 8. The portion of the electrode structure 128 can refer to the fingers 312. In particular, the dielectric 130 extends past the first surface 502-1 of the fingers 312 towards the piezoelectric layer 302 and defines a cavity 318. The cavity 318 can have a similar or larger width as the fingers 312 of the electrode structure 128. Also, the cavity 318 can have a similar or smaller length as the fingers 312 of the electrode structure 128. In some cases, the dielectric 130 abuts the piezoelectric layer 302. Optionally, the manufacturing process can also provide one or more of the dielectric layers 602-1 to 602-3 of FIG. 6.

An etching process can be used to suspend the electrode structure 128 using the dielectric 130. In this case, the manufacturing process provides a sacrificial structure, such as an amorphous silicon (a-Si) layer, on the piezoelectric layer 302. For instance, the sacrificial structure can be provided after the step described at 902 and before the step described at 904. The sacrificial structure defines a volume and position of the cavity 318 and is removed later in the manufacturing process. Optionally, the manufacturing process provides the dielectric layer 602-2 to provide a layer of protection for the electrode structure 128 during the removal of the sacrificial layer. After providing the dielectric 130 at 906, the manufacturing process etches through the cap 314 and/or spacers 316 to access the sacrificial structure. The manufacturing process removes the sacrificial structure using a chemical, such as xenon difluoride (XeF₂), to form a volume for the cavity 318 between the surface 502-1 of the portion of the electrode structure 128 (e.g., the fingers 312) and the piezoelectric layer 302.

Wafer bonding can also be used to suspend the electrode structure 128 using the dielectric 130. In this case, the manufacturing process provides the piezoelectric layer 302, as described at 902, on a first wafer. Also, the manufacturing process provides the electrode structure 128 and the dielectric 130, as described at 904 and 906, on a second wafer. The manufacturing process bonds the first wafer to the second wafer to form the cavity 318 between the surface 502-1 of the portion of the electrode structure 128 and the piezoelectric layer 302.

Some aspects are described below.

Aspect 1: An apparatus comprising:
a surface-acoustic-wave filter comprising:
   a piezoelectric layer;
   an electrode structure having a first surface facing the piezoelectric layer and separated from the piezoelectric layer by a distance; and
   a dielectric disposed on at least one other surface of the electrode structure and configured to extend past a plane defined by the first surface of the electrode structure and toward the piezoelectric layer to define a cavity between the first surface of the electrode structure and the piezoelectric layer.

Aspect 2: The apparatus of aspect 1, wherein the dielectric is configured to cause at least a portion of the electrode structure to be suspended apart from the piezoelectric layer by the distance.

Aspect 3: The apparatus of aspect 1 or 2, wherein the dielectric adheres to the at least one other surface of the electrode structure.

Aspect 4: The apparatus of any previous aspect, wherein portions of the dielectric extend past the plane through different gaps in the electrode structure.

Aspect 5: The apparatus of any previous aspect, wherein:
the electrode structure comprises multiple gaps; and
at least a portion of the dielectric is present within the multiple gaps and abuts the piezoelectric layer.

Aspect 6: The apparatus of any previous aspect, wherein the cavity is at least partially filled with a gas.

Aspect 7: The apparatus of aspect 6, wherein the gas comprises air.

Aspect 8: The apparatus of any previous aspect, wherein:
the electrode structure comprises:
   a first comb-shaped structure comprising a first busbar and a first set of fingers extending from the first busbar; and
   a second comb-shaped structure comprising a second busbar and a second set of fingers extending from the second busbar; and
the cavity is present between the piezoelectric layer and fingers of the first set of fingers and the second set of fingers.

Aspect 9: The apparatus of aspect 8, wherein:
the at least one other surface of the electrode structure comprises a second surface that faces at least partially away from the piezoelectric layer; and
the dielectric comprises:
   a cap disposed across the second surface of the fingers; and
   spacers disposed between the piezoelectric layer and the cap through gaps present between the fingers.

Aspect 10: The apparatus of aspect 9, wherein the cap and the spacers comprise a same dielectric material.

Aspect 11: The apparatus of aspect 9 or 10, wherein a thickness of the cap is between approximately one hundred nanometers and two thousand nanometers.

Aspect 12: The apparatus of any one of aspects 8 to 11, wherein the cavity extends along lengths of the fingers.

Aspect 13: The apparatus of any one of aspects 8 to 12, wherein a width of the cavity is greater than individual widths of the fingers.

Aspect 14: The apparatus of any previous aspect, wherein the dielectric comprises one or more of the following:
a layer of silicon dioxide;
a layer of nitride;
a layer of aluminum oxide;
a layer of polymer;
a layer of titanium dioxide;
a layer of hafnium dioxide;
a layer of yttrium oxide; or
a layer of zirconium dioxide.

Aspect 15: The apparatus of any previous aspect, wherein a height of the cavity is between approximately one nanometer and fifty nanometers.

Aspect 16: The apparatus of any previous aspect, wherein the piezoelectric layer is configured to excite one of the following:
a shear mode;
a Rayleigh mode; or
a longitudinal mode.

Aspect 17: The apparatus of any previous aspect, wherein the surface-acoustic-wave filter comprises at least one of the following:
a first dielectric layer that is disposed between the dielectric and the electrode structure, disposed between the dielectric and the piezoelectric layer, and disposed between the dielectric and the cavity;
a second dielectric layer that is disposed between the first surface of the electrode structure and the cavity; or
a third dielectric layer that is disposed between the piezoelectric layer and the cavity and disposed between the piezoelectric layer and the dielectric.

Aspect 18: The apparatus of aspect 17, wherein:
the surface-acoustic-wave filter comprises the first dielectric layer; and
the first dielectric layer has a thickness between approximately one and one hundred nanometers.

Aspect 19: The apparatus of aspect 17 or 18, wherein:
the surface-acoustic-wave filter comprises the second dielectric layer or the third dielectric layer; and
the second dielectric layer or the third dielectric layer has a thickness between approximately one and five nanometers.

Aspect 20: The apparatus of any previous aspect, wherein:
the surface-acoustic-wave filter comprises multiple cascaded resonators; and
a resonator of the multiple cascaded resonators comprises the piezoelectric layer and the dielectric.

Aspect 21: The apparatus of any previous aspect, further comprising:
a wireless transceiver coupled to at least one antenna, the wireless transceiver comprising the surface-acoustic-wave filter and configured to filter, using the surface-acoustic-wave filter, a wireless signal communicated via the at least one antenna.

Aspect 22: The apparatus of any previous aspect, wherein the surface-acoustic-wave filter comprises a thin-film surface-acoustic-wave filter.

Aspect 23: An apparatus comprising:
a surface-acoustic-wave filter configured to generate a filtered signal from a radio-frequency signal, the surface-acoustic-wave filter comprising:
   means for converting the radio-frequency signal to an acoustic wave and converting a propagated acoustic wave into the filtered signal;
   means for propagating the acoustic wave across a planar surface to produce the propagated acoustic wave; and
   means for suspending at least a portion of the means for converting apart from the planar surface.

Aspect 24: The apparatus of aspect 23, wherein the means for suspending comprises means for reflecting the acoustic wave.

Aspect 25: A method of manufacturing a surface-acoustic-wave filter, the method comprising:
providing a piezoelectric layer;
providing an electrode structure having a first surface facing the piezoelectric layer and separated from the piezoelectric layer by a distance; and
providing a dielectric that suspends at least a portion of the first surface of the electrode structure apart from the piezoelectric layer by the distance.

Aspect 26: The method of aspect 25, further comprising:
providing a sacrificial layer on a surface of the piezoelectric layer, the sacrificial layer present between the piezoelectric layer and the portion of the first surface of the electrode structure;
etching through the dielectric to the sacrificial layer; and
removing the sacrificial layer to form a cavity between the portion of the first surface of the electrode structure and the piezoelectric layer.

Aspect 27: The method of aspect 25, wherein:
the providing of the piezoelectric layer comprises providing the piezoelectric layer on a first wafer;
the providing of the electrode structure and the providing of the dielectric comprises providing the electrode structure and the dielectric on a second wafer; and
the method further comprises:
   bonding the first wafer to the second wafer to form a cavity between the portion of the first surface of the electrode structure and the piezoelectric layer.

Aspect 28: A surface-acoustic-wave filter comprising:
a piezoelectric layer having a planar surface;
an electrode structure comprising fingers, the fingers having a first surface facing the planar surface of the piezoelectric layer and a second surface facing at least partially away from the piezoelectric layer; and
a dielectric configured to separate the fingers of the electrode structure from the planar surface of the piezoelectric layer, the dielectric comprising:
   a cap disposed across the second surface of the fingers; and
   spacers disposed between the piezoelectric layer and the cap through gaps that are present between the fingers.

Aspect 29: The surface-acoustic-wave filter of aspect 28, wherein the spacers of the dielectric are configured to extend past a plane defined by the first surface of the fingers toward the planar surface of the piezoelectric layer to define a cavity between the first surface of the fingers and the planar surface of the piezoelectric layer.

Aspect 30: The surface-acoustic-wave filter of aspect 29, wherein the cavity extends along lengths of the fingers and extends beyond widths of the fingers.

Aspect 31: The surface-acoustic-wave filter of aspect 29 or 30, wherein the surface-acoustic-wave filter comprises a dielectric layer that is disposed between the dielectric and the fingers, disposed between the dielectric and the piezoelectric layer, and disposed between the dielectric and the cavity.

Aspect 32: The surface-acoustic-wave filter of any one of aspects 29 to 31, wherein the surface-acoustic-wave filter comprises a dielectric layer that is disposed between the fingers and the cavity.

Aspect 33: The surface-acoustic-wave filter of any one of aspects 29 to 32, wherein the surface-acoustic-wave filter comprises a dielectric layer that is disposed between the piezoelectric layer and the cavity and disposed between the piezoelectric layer and the dielectric.

Aspect 34: The surface-acoustic-wave filter of any one of aspects 28 to 33, wherein the cap and the spacers comprise different dielectric materials.

Aspect 35: The surface-acoustic-wave filter of any one of aspects 28 to 34, wherein:
the surface-acoustic-wave filter is configured to generate a standing surface acoustic wave across the planar surface of the piezoelectric layer; and
the spacers are positioned at nodes of the standing surface acoustic wave.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a surface-acoustic-wave filter comprising:
a piezoelectric layer;
an electrode structure having a first surface facing the piezoelectric layer and separated from the piezoelectric layer by a distance; and
a dielectric disposed on at least one other surface of the electrode structure and configured to extend past a plane defined by the first surface of the electrode structure and toward the piezoelectric layer to define a cavity between the first surface of the electrode structure and the piezoelectric layer.

2. The apparatus of claim 1, wherein the dielectric is configured to cause at least a portion of the electrode structure to be suspended apart from the piezoelectric layer by the distance.

3. The apparatus of claim 1, wherein the dielectric adheres to the at least one other surface of the electrode structure.

4. The apparatus of claim 1, wherein portions of the dielectric extend past the plane through different gaps in the electrode structure.

5. The apparatus of claim 1, wherein:
the electrode structure comprises multiple gaps; and
at least a portion of the dielectric is present within the multiple gaps and abuts the piezoelectric layer.

6. The apparatus of claim 1, wherein the cavity is at least partially filled with a gas.

7. The apparatus of claim 6, wherein the gas comprises air.

8. The apparatus of claim 1, wherein:
the electrode structure comprises:
a first comb-shaped structure comprising a first busbar and a first set of fingers extending from the first busbar; and
a second comb-shaped structure comprising a second busbar and a second set of fingers extending from the second busbar; and
the cavity is present between the piezoelectric layer and fingers of the first set of fingers and the second set of fingers.

9. The apparatus of claim 8, wherein:
the at least one other surface of the electrode structure comprises a second surface that faces at least partially away from the piezoelectric layer; and
the dielectric comprises:
a cap disposed across the second surface of the fingers; and
spacers disposed between the piezoelectric layer and the cap through gaps present between the fingers.

10. The apparatus of claim 9, wherein the cap and the spacers comprise a same dielectric material.

11. The apparatus of claim 9, wherein a thickness of the cap is between approximately one hundred nanometers and two thousand nanometers.

12. The apparatus of claim 8, wherein the cavity extends along lengths of the fingers.

13. The apparatus of claim 8, wherein a width of the cavity is greater than individual widths of the fingers.

14. The apparatus of claim 1, wherein the dielectric comprises one or more of the following:
a layer of silicon dioxide;
a layer of nitride;
a layer of aluminum oxide;
a layer of polymer;
a layer of titanium dioxide;
a layer of hafnium dioxide;
a layer of yttrium oxide; or
a layer of zirconium dioxide.

15. The apparatus of claim 1, wherein a height of the cavity is between approximately one nanometer and fifty nanometers.

16. The apparatus of claim 1, wherein the piezoelectric layer is configured to excite one of the following:
a shear mode;
a Rayleigh mode; or
a longitudinal mode.

17. The apparatus of claim 1, wherein the surface-acoustic-wave filter comprises at least one of the following:
a first dielectric layer that is disposed between the dielectric and the electrode structure, disposed between the dielectric and the piezoelectric layer, and disposed between the dielectric and the cavity;
a second dielectric layer that is disposed between the first surface of the electrode structure and the cavity; or
a third dielectric layer that is disposed between the piezoelectric layer and the cavity and disposed between the piezoelectric layer and the dielectric.

18. The apparatus of claim 17, wherein:
the surface-acoustic-wave filter comprises the first dielectric layer; and
the first dielectric layer has a thickness between approximately one and one hundred nanometers.

19. The apparatus of claim 17, wherein:
the surface-acoustic-wave filter comprises the second dielectric layer or the third dielectric layer; and
the second dielectric layer or the third dielectric layer has a thickness between approximately one and five nanometers.

20. The apparatus of claim 1, wherein:
the surface-acoustic-wave filter comprises multiple cascaded resonators; and
a resonator of the multiple cascaded resonators comprises the piezoelectric layer and the dielectric.

21. The apparatus of claim 1, further comprising:
a wireless transceiver coupled to at least one antenna, the wireless transceiver comprising the surface-acoustic-wave filter and configured to filter, using the surface-acoustic-wave filter, a wireless signal communicated via the at least one antenna.

22. The apparatus of claim 1, wherein the surface-acoustic-wave filter comprises a thin-film surface-acoustic-wave filter.

23. An apparatus comprising:
a surface-acoustic-wave filter configured to generate a filtered signal from a radio-frequency signal, the surface-acoustic-wave filter comprising:
means for converting the radio-frequency signal to an acoustic wave and converting a propagated acoustic wave into the filtered signal;
means for propagating the acoustic wave across a planar surface to produce the propagated acoustic wave; and
means for suspending at least a portion of the means for converting apart from the planar surface.

24. The apparatus of claim 23, wherein the means for suspending comprises means for reflecting the acoustic wave.

25. A method of manufacturing a surface-acoustic-wave filter, the method comprising:
providing a piezoelectric layer;
providing an electrode structure having a first surface facing the piezoelectric layer and separated from the piezoelectric layer by a distance; and
providing a dielectric that suspends at least a portion of the first surface of the electrode structure apart from the piezoelectric layer by the distance.

26. The method of claim 25, further comprising:
providing a sacrificial layer on a surface of the piezoelectric layer, the sacrificial layer present between the piezoelectric layer and the portion of the first surface of the electrode structure;
etching through the dielectric to the sacrificial layer; and
removing the sacrificial layer to form a cavity between the portion of the first surface of the electrode structure and the piezoelectric layer.

27. The method of claim 25, wherein:
the providing of the piezoelectric layer comprises providing the piezoelectric layer on a first wafer;
the providing of the electrode structure and the providing of the dielectric comprises providing the electrode structure and the dielectric on a second wafer; and
the method further comprises:
bonding the first wafer to the second wafer to form a cavity between the portion of the first surface of the electrode structure and the piezoelectric layer.

28. A surface-acoustic-wave filter comprising:
a piezoelectric layer having a planar surface;
an electrode structure comprising fingers, the fingers having a first surface facing the planar surface of the piezoelectric layer and a second surface facing at least partially away from the piezoelectric layer; and
a dielectric configured to separate the fingers of the electrode structure from the planar surface of the piezoelectric layer, the dielectric comprising:
a cap disposed across the second surface of the fingers; and
spacers disposed between the piezoelectric layer and the cap through gaps that are present between the fingers.

29. The surface-acoustic-wave filter of claim 28, wherein the spacers of the dielectric are configured to extend past a plane defined by the first surface of the fingers toward the planar surface of the piezoelectric layer to define a cavity between the first surface of the fingers and the planar surface of the piezoelectric layer.

30. The surface-acoustic-wave filter of claim 29, wherein the cavity extends along lengths of the fingers and extends beyond widths of the fingers.

31. The surface-acoustic-wave filter of claim 29, wherein the surface-acoustic-wave filter comprises a dielectric layer that is disposed between the dielectric and the fingers, disposed between the dielectric and the piezoelectric layer, and disposed between the dielectric and the cavity.

32. The surface-acoustic-wave filter of claim 29, wherein the surface-acoustic-wave filter comprises a dielectric layer that is disposed between the fingers and the cavity.

33. The surface-acoustic-wave filter of claim 29, wherein the surface-acoustic-wave filter comprises a dielectric layer that is disposed between the piezoelectric layer and the cavity and disposed between the piezoelectric layer and the dielectric.

34. The surface-acoustic-wave filter of claim 28, wherein the cap and the spacers comprise different dielectric materials.

35. The surface-acoustic-wave filter of claim 28, wherein:
the surface-acoustic-wave filter is configured to generate a standing surface acoustic wave across the planar surface of the piezoelectric layer; and
the spacers are positioned at nodes of the standing surface acoustic wave.
